(19) United States
(12) Patent Application Publication
(10) Pub. No.: US 2024/0153868 A1
(43) Pub. Date: May 9, 2024

(54) INTERCONNECT STRUCTURE WITH SKIPVIA

(71) Applicant: INTERNATIONAL BUSINESS MACHINES CORPORATION, Armonk, NY (US)

(72) Inventors: Koichi Motoyama, Clifton Park, NY (US); Oscar van der Straten, Guilderland Center, NY (US); Ruilong Xie, Niskayuna, NY (US); Chih-Chao Yang, Glenmont, NY (US)

(21) Appl. No.: 18/053,772

(22) Filed: Nov. 9, 2022

(51) Int. Cl. H01L 23/522; H01L 21/768; H01L 23/532

(52) U.S. Cl. CPC H01L 23/5226; H01L 21/76807; H01L 21/76843; H01L 21/76877; H01L 23/53238; H01L 23/53266

(57) ABSTRACT

Embodiments of present invention provide an interconnect structure. The interconnect structure includes a first metal line in a first inter-level dielectric (ILD) layer; one or more second metal lines in a second ILD layer above the first metal line and above the first ILD layer; a third metal line in a third ILD layer above the one or more second metal lines and above the second ILD layer; and a skipvia connecting the third metal line with the first metal line, wherein the first, the one or more second, and the third metal lines are made of a first conductive material and the skipvia is made of a second conductive material, and the first conductive material is different from the second conductive material. A method of forming the above interconnect structure is also provided.

### BACKGROUND

The present application relates to manufacturing of semiconductor integrated circuits. More particularly, it relates to method of forming an interconnect structure with a skipvia.

Semiconductor integrated circuits often include active devices such as, for example, various field-effect-transistors (FETs) in the front-end-of-line (FEOL) region and interconnect structures in the back-end-of-line (BEOL) that provides device biasing, powering, and signal routing functionalities, among others. An interconnect structure may generally include multiple metal levels and each metal level may include one or more metal lines and one or more contact vias that connect metal lines at different metal levels together. Commonly, copper is used in forming the various metal lines and contact vias because of its relatively low resistance and other advanced feature. However, it is known to be challenging for copper to fill narrow spaces such as small via openings. This becomes a particular concern when it comes forming a contact via that skips at least one metal level to connect two metal lines in two separated metal levels, instead of metal lines in two adjacent metal levels. This is because such contact via usually has a very high aspect ratio.

### SUMMARY

Embodiments of present invention provide an interconnect structure. The structure includes a first metal line in a first inter-level dielectric (ILD) layer; one or more second metal lines in a second ILD layer above the first metal line and above the first ILD layer; a third metal line in a third ILD layer above the one or more second metal lines and above the second ILD layer; and a skipvia connecting the third metal line with the first metal line, wherein the first, the one or more second, and the third metal lines are made of a first conductive material and the skipvia is made of a second conductive material, the first conductive material being different from the second conductive material.

In one embodiment, the second conductive material is ruthenium (Ru), and in another embodiment, the first conductive material is copper (Cu).

According to one embodiment, the interconnect structure may further include a first contact via connecting one of the one or more second metal lines with the first metal line, wherein the first contact via is made of the first conductive material.

According to another embodiment, the interconnect structure may further include a second contact via connecting the third metal line with another one of the one or more second metal lines, wherein the second contact via is made of the second conductive material.

According to yet another embodiment, the interconnect structure may further include a barrier layer directly surrounding sidewalls and a bottom of the skipvia.

According to one embodiment, the interconnect structure may further include a conductive liner directly lining the third metal line, and wherein the conductive liner is substantially surrounded by the barrier layer.

In one embodiment, the conductive liner is on top of and in direct contact with the skipvia. In another embodiment, the barrier layer is a layer of tantalum-nitride (TaN) and the conductive liner is a layer of cobalt (Co).

Embodiments of present invention also provide a method of forming an interconnect structure. The method includes forming a first inter-level dielectric (ILD) layer with a first metal line of a first conductive material embedded therein; forming a second ILD layer, with multiple second metal lines of the first conductive material embedded therein, on top of the first ILD layer; forming a third ILD layer on top of the second ILD layer; creating a first via opening in the third ILD layer, the first via opening extending through the second ILD layer to expose the first metal line in the first ILD layer; filling the first via opening with a second conductive material to form a skipvia; and forming a third metal line of the first conductive material in the third ILD layer, the third metal line being on top of and in contact with the skipvia, wherein the first conductive material is copper (Cu), and the second conductive material is ruthenium (Ru).

In one embodiment, the method further includes creating a trench opening in a damascene patterning and etching process in the third ILD layer; before filling the first via opening, forming a barrier layer at sidewalls and bottoms of the first via opening and the trench opening; and after filling the first via opening, removing the second conductive material in the trench opening and recessing the second conductive material in the first via opening.

In another embodiment, the method further includes, before forming the third metal line, forming a conductive liner in the trench opening above the barrier layer and directly above the skipvia; and filling the trench opening with the first conductive material to form the third metal line.

In yet another embodiment, the method further includes creating a second via opening in the third ILD layer to expose one of the multiple second metal lines in the second ILD layer; and filling the second via opening with the second conductive material to form a contact via.

### BRIEF DESCRIPTION OF THE DRAWINGS

The present invention will be understood and appreciated more fully from the following detailed description of embodiments of present invention, taken in conjunction with accompanying drawings of which:

FIGS. 1-11 are demonstrative illustrations of cross-sectional views of an interconnect structure with a skipvia in a process of manufacturing thereof according to embodiments of present invention; and

FIG. 12 is a demonstrative illustration of a flow-chart of a method of manufacturing an interconnect structure with a skipvia according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

To provide spatial context to different structural orientations of the semiconductor structures shown in the drawings, XYZ Cartesian coordinates may be provided in some of the drawings. The terms “vertical” or “vertical direction” or “vertical height” as used herein denote a Z-direction of the Cartesian coordinates shown in the drawings, and the terms “horizontal” or “horizontal direction” or “lateral direction” as used herein denote an X-direction and/or a Y-direction of the Cartesian coordinates shown in the drawings.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

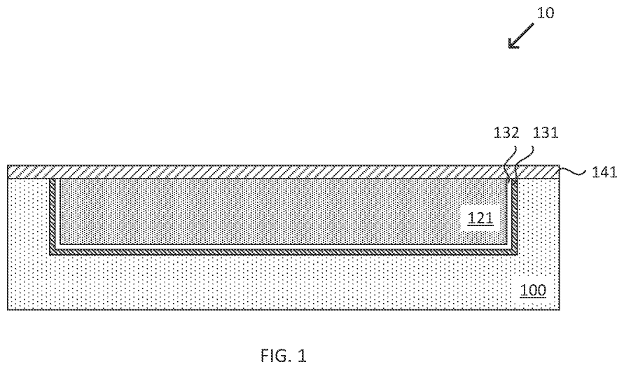

FIG. 1 is a demonstrative illustration of cross-sectional view of an interconnect structure with a skipvia in a step of manufacturing thereof according to one embodiment of present invention. More particularly, embodiments of present invention may provide forming an interconnect structure 10 by forming a first inter-level dielectric (ILD) layer 100 with a first metal line 121 embedded therein. The first ILD layer 100, together with the first metal line 121 therewithin, may be known as a metal level such as a metal level-1 (M1), a metal level-2 (M2), etc. and may be collectively referred to, hereinafter for reference purpose, as a metal level x (M−x). The first ILD layer 100 may be a low-k dielectric material such as, for example, silicon-oxide (SiO, SiO2), silicon-carbon-oxide (SiCO, SiCOH), and/or other suitable low-k dielectric materials. On the other hand, the first metal line 121 may include or be made of a first conductive material such as, for example, copper (Cu), aluminum (Al), tungsten (W) or other suitable conductive materials.

In forming the first metal line 121, an opening, more particularly a trench opening, may be created in the first ILD layer 100. A barrier layer 131 may subsequently be formed at sidewall and bottom of the trench opening. The barrier layer 131 may be a layer of tantalum-nitride (TaN), titanium-nitride (TiN), or other suitable barrier materials and may be formed through a deposition process such as, for example, an atomic-layer deposition (ALD) process, a chemical-vapor deposition (CVD) process, or a physical-vapor deposition (PVD) process. The barrier layer 131 may be formed to mitigate possible diffusion of conductive material, used by the first metal line 121, into surrounding low-k dielectric material of the first ILD layer 100 causing dielectric contamination.

Following the step of forming the barrier layer 131, embodiments of present invention provide forming a conductive liner 132 on top of the barrier layer 131. The conductive liner 132 may be a layer of cobalt (Co) and may be formed through a deposition process such as an ALD process, a CVD process, or a PVD process. Embodiments of present invention further provide filling the trench opening with the first conductive material to form the first metal line 121. In one embodiment, the first metal line 121, surrounded by the conductive liner 132 at sidewalls and a bottom thereof, may be formed through a deposition process such as an ALD process, a CVD process, or combination of a PVD process and a plating process.

Following the deposition, excessive portions of the first conductive material, and any excessive portions of materials of the conductive liner 132 and the barrier layer 131 that are above the first ILD layer 100, may be removed by subjecting the interconnect structure 10 to a polishing process such as a chemical-mechanic-polishing (CMP) process. The CMP process may remove materials above a level of the first ILD layer 100, at least until the top surface of the first ILD layer 100 is exposed, to produce a planarized top surface. Embodiments of present invention further provide forming a dielectric cap layer 141 at the planarized top surface, more particularly above the first ILD layer 100 and the first metal line 121. In one embodiment, the dielectric cap layer 141 may be a layer of silicon-carbonitride (SiCN) and may be used as an etch-stop-layer (ESL) during subsequent lithographic patterning and etching processes.

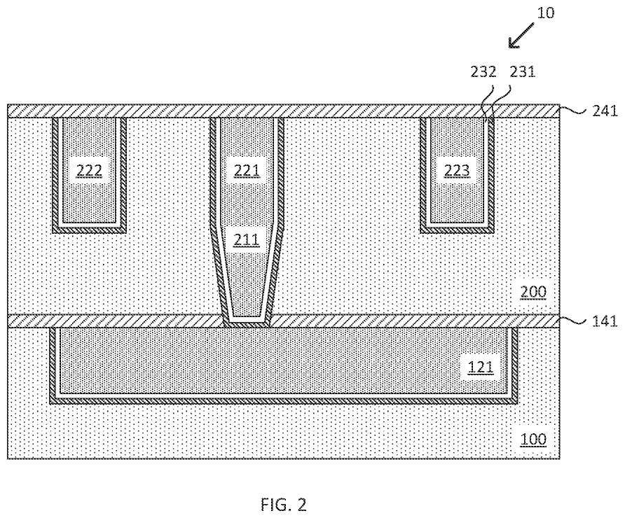

FIG. 2 is a demonstrative illustration of cross-sectional view of an interconnect structure with a skipvia in a step of manufacturing thereof according to one embodiment of present invention. More particularly, embodiments of present invention provide forming a second ILD layer 200 above, or on top of, the first ILD layer 100 and the first metal line 121. The second ILD layer 200 may be formed to have one or more second metal lines, such as second metal lines 221, 222, and 223, embedded therein and may have one or more contact vias, such as a first contact via 211. The first contact via 211 may extend through the dielectric cap layer 141 to connect, for example, the second metal line 221 with the first metal line 121. The second ILD layer 200, together with the one or more second metal lines 221, 222, and 223 and the one or more contact vias such as the first contact via 211, may be collectively referred to as a metal level x+1 (M−x+1).

The second metal lines 221, 222, and 223 and the first contact via 211 may be made by first creating at least one via opening for forming the first contact via 211 and creating one or more trench openings for forming the second metal lines 221, 222, and 223. The via opening and trench openings may be made in the second ILD layer 200 through a damascene lithographic patterning and etching process. In the case of forming the first contact via 211, the via opening may be created that goes through the dielectric cap layer 141 underneath the second ILD layer 200. After the via opening and trench openings are created, embodiments of present invention provide forming a barrier layer 231, which may be a layer of TaN, TiN, or other suitable materials, and subsequently a conductive liner 232, which may be a layer of Co, in the via opening and trench openings. For example, the barrier layer 231 and the conductive liner 232 may be formed at sidewalls and bottoms of the via opening and trench openings.

Next, embodiments of present invention provide depositing a conductive material, such as the first conductive material of Cu, in the via opening and the trench openings, directly above the conductive liner 232, to form the first contact via 211 and the one or more second metal lines 221, 222, and 223. Thus, the first contact via 211 and the one or more second metal lines 221, 222, and 223 may be made of Cu. Here, it is noted that the first contact via 211 and the second metal line 221 may be formed in a same deposition process of the first conductive material. After filling the via opening and the trench openings with the first conductive material, and after applying a CMP process to planarize the top surface of the interconnect structure 10, a dielectric cap layer 241 may be formed on top of the second ILD layer 200 and the one or more second metal lines 221, 222, and 223. The dielectric cap layer 241 may be function as an ESL during subsequent lithographic patterning and etching process and may be made of, for example, SiCN or other suitable material. For example, the dielectric cap layer 241 may have an etch-selectivity different from that of the second ILD layer 200 to serve as an ESL.

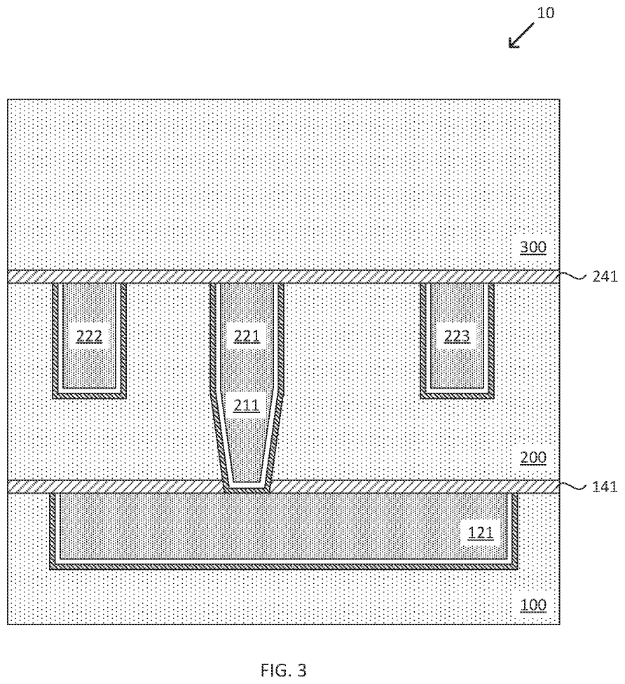

FIG. 3 is a demonstrative illustration of cross-sectional view of an interconnect structure with a skipvia in a step of manufacturing thereof according to one embodiment of present invention. More particularly, embodiments of present invention provide forming a third ILD layer 300 above, or on top of, the second ILD layer 200 and the one or more second metal lines 221, 222, and 223. The third ILD layer 300 may be used to form a metal level x+2 (M−x+2), as being described below in more details.

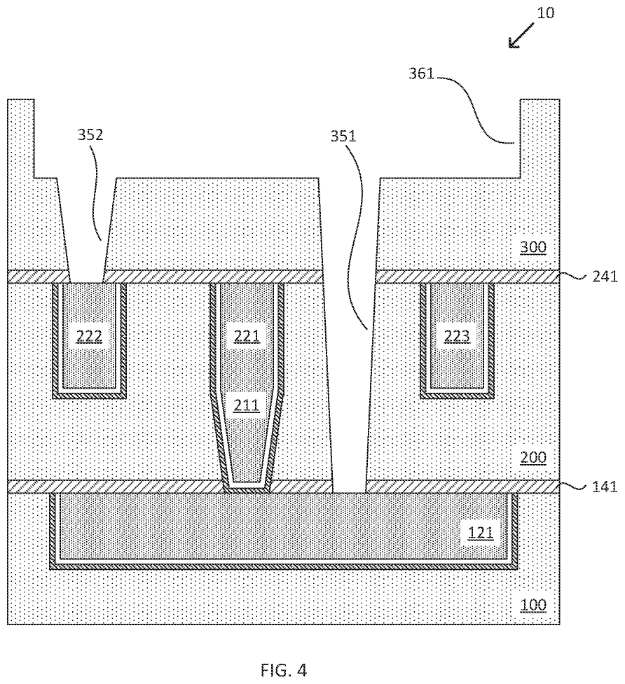

FIG. 4 is a demonstrative illustration of cross-sectional view of an interconnect structure with a skipvia in a step of manufacturing thereof according to one embodiment of present invention. More particularly, embodiments of present invention provide creating one or more via openings, such as via openings 351 and 352, and at least one trench opening, such as a trench opening 361, in the third ILD layer 300 in a damascene lithographic patterning and etching process. More specifically, the via opening 351 may be created such that it extends through the dielectric cap layer 241, the second ILD layer 200, and the dielectric cap layer 141 to expose the first metal line 121. In other words, the via opening 351 may be created for forming a skipvia as being described below in more details.

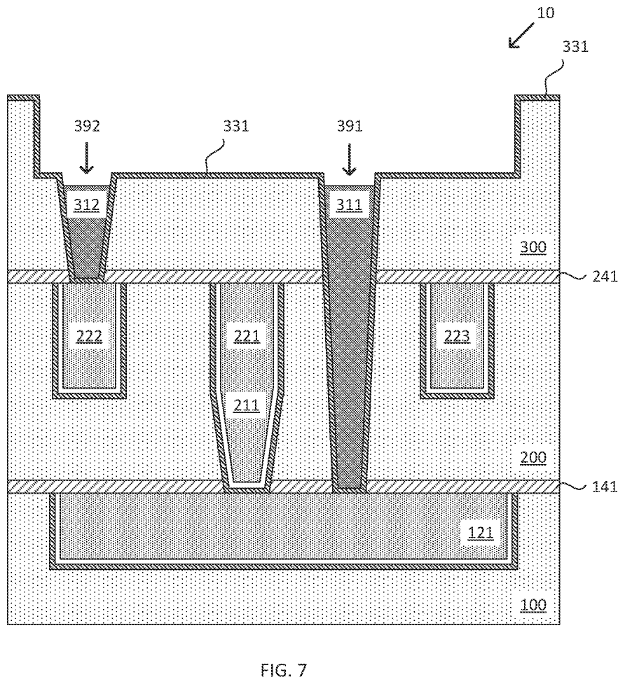

Generally, a skipvia refers to a contact via that is sufficiently deep to connect two metal levels, or more specifically two metal lines in the two metal levels, that are not vertically adjacent to each other. For example, as is demonstratively illustrated in FIG. 4, the via opening 351 may be used to form a skipvia that connects the first metal line 121 in the first ILD layer 100 of a metal level M-x with a third metal line 321 (see FIG. 7) in the third ILD layer 300 of a metal level M−x+2, skipping a metal level M−x+1 there-in-between that includes the one or more second metal lines 221, 222, and 223 in the second ILD layer 200.

Embodiments of present invention also provide creating the via opening 352 in the third ILD layer 300. The via opening 352 extends through the dielectric cap layer 241 to expose one of the one or more second metal lines 221, 222, and 223, such as the second metal line 222, in the second ILD layer 200. During the damascene patterning and etching process in creating the via openings 351 and 352, the trench opening 361 may be created as well above the via openings 351 and 352 to partially overlap with the via openings 351 and 352. The third metal line 321 formed in the trench opening 361 thus may be connected to contact vias formed in the via openings 351 and 352.

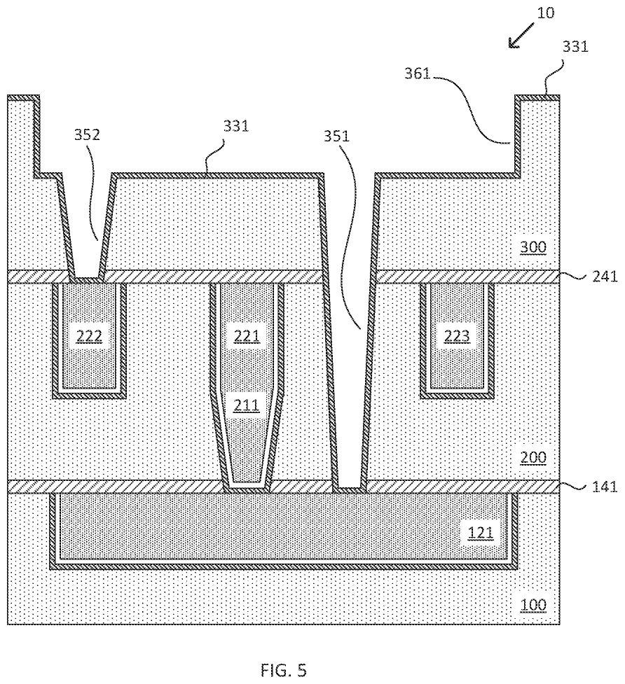

FIG. 5 is a demonstrative illustration of cross-sectional view of an interconnect structure with a skipvia in a step of manufacturing thereof according to one embodiment of present invention. More particularly, embodiments of present invention provide forming a barrier layer 331 lining sidewalls and bottoms of the via openings 351, 352 and the trench opening 361. The barrier layer 331 may be, for example, a layer of TaN, TiN, or other suitable material and may be formed through an ALD process. However, embodiments of present invention are not limited in this aspect and other method of forming the barrier layer 331, such as a CVD process, a PVD process, or any other currently existing or future developed methods may be used as well.

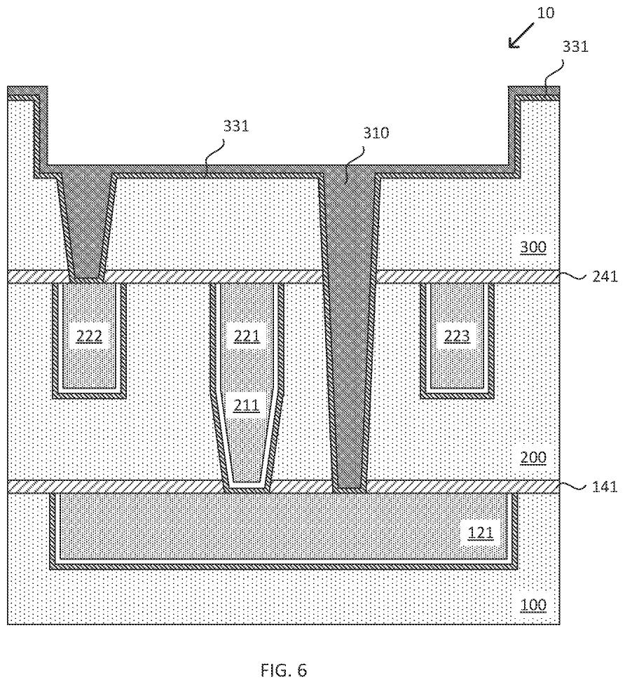

FIG. 6 is a demonstrative illustration of cross-sectional view of an interconnect structure with a skipvia in a step of manufacturing thereof according to one embodiment of present invention. More particularly, embodiments of present invention provide filling the via opening 351 with a second conductive material to form a skipvia. Generally, since the via opening 351 is formed for forming a skipvia and thus having a deep opening with a high aspect-ratio (A/R) generally around 5 to 20, it is known in the art that conductive materials that are commonly used in forming the first metal line 121 and the second metal lines 221, 222, and 223 may not be able to fill the via opening 351 completely without creating some void. For example, the first conductive material of Cu may be used in forming the first metal line 121, the one or more second metal lines 221, 222, and 223, and a third metal line as being described below in more details. However, using the first conductive material of Cu in forming a skipvia in the via opening 351, which has an aspect-ratio of as high as 20, may lead to the creation of void in the skipvia.

Embodiments of present invention provide filling the via opening 351, above the barrier layer 331, with a second conductive material that is different from the first conductive material of Cu. For example, embodiments of present invention provide filling the via opening 351 with a second conductive material of ruthenium (Ru), and the Ru may fill the via opening 351 near completely without creating any voids or any meaningful voids. More specifically, the second conductive material of Ru may be deposited through a CVD process to fill the via opening 351 as well as the via opening 352. In one embodiment, the deposition process of Ru in the via openings 351 and 352 may also partially fill the trench opening 361.

FIG. 7 is a demonstrative illustration of cross-sectional view of an interconnect structure with a skipvia in a step of manufacturing thereof according to one embodiment of present invention. More particularly, embodiments of present invention provide removing the second conductive material of Ru in the trench opening 361 through an isotropic dry-etching process, thereby leaving the second conductive material of Ru only in the via openings 351 and 352 to form a skipvia 311 and a contact via 312. The dry-etching process in removing Ru in the trench opening 361 may be selective to the barrier layer 331. In one embodiment, the process of removing Ru in the trench opening 361 may also create recesses, to certain extent, of the conductive material Ru in the via openings 351 and 352, thereby creating dips or openings 391 and 392 of a step shape directly above the skipvia 311 and the contact via 312.

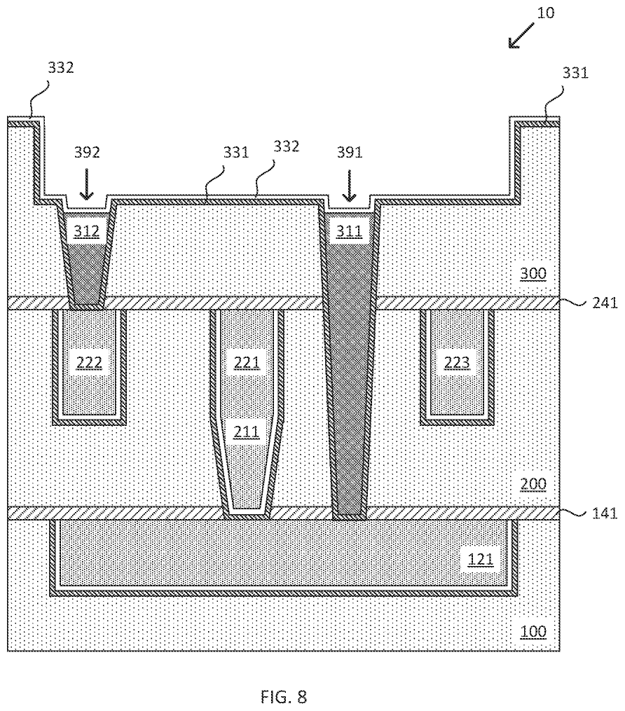

FIG. 8 is a demonstrative illustration of cross-sectional view of an interconnect structure with a skipvia in a step of manufacturing thereof according to one embodiment of present invention. More particularly, embodiments of present invention provide forming a conductive liner 332 directly above the barrier layer 331 and directly above the skipvia 311 and the contact via 312 in the openings 391 and 392. The conductive liner 332 may be a layer of Co and may be formed through a deposition process such as an ALD process, a CVD process, or a PVD process. It is to be noted here that there is no barrier layer 331 in the openings 391 and 392 between the skipvia 311 and the conductive liner 332, and between the contact via 312 and the conductive liner 332. The absence of the barrier layer 331 between the skipvia 311 and the third metal line 321 (to be formed thereupon) helps reduce resistance between the two and similarly it helps reduce the resistance between the contact via 312 and the third metal line 321.

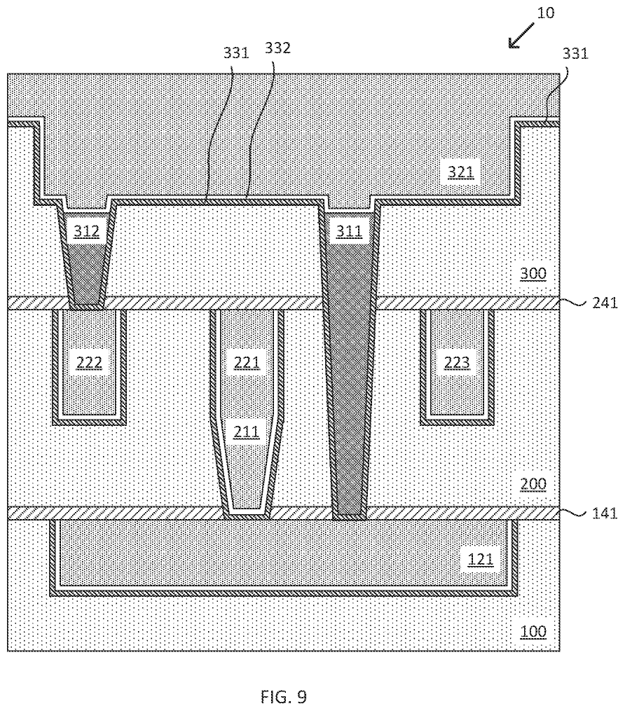

FIG. 9 is a demonstrative illustration of cross-sectional view of an interconnect structure with a skipvia in a step of manufacturing thereof according to one embodiment of present invention. More particularly, embodiments of present invention provide filling the trench opening 361, including the dips or step-shaped openings 391 and 392 above the skipvia 311 and contact via 312, with the first conductive material such as the first conductive material of Cu. The first conductive material may be deposited directly on top of the conductive liner 332 through a PVG process followed by a plating process, thereby forming a third metal line 321. In one embodiment, as is illustrated in FIG. 9, the third metal line 321 may include one or more lowered portions of step shape, covered at a bottom thereof by the conductive liner 332, and directly on top of the skipvia 311 and the contact via 312.

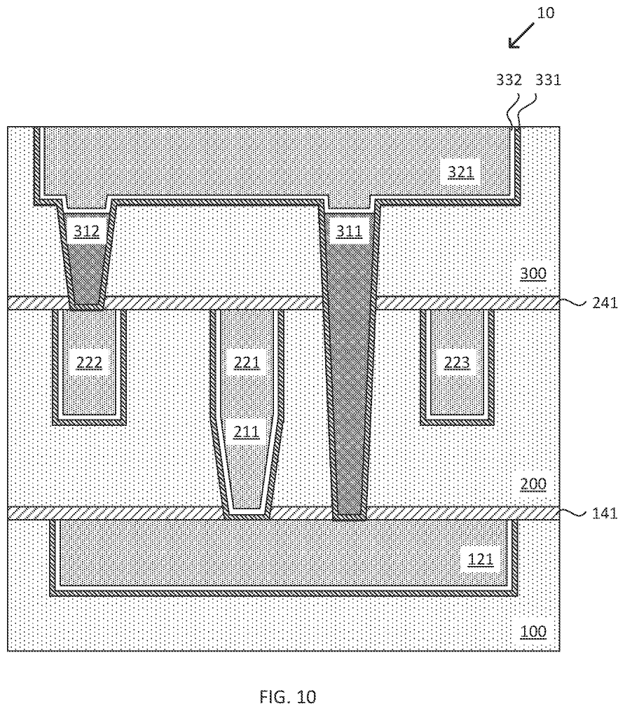

FIG. 10 is a demonstrative illustration of cross-sectional view of an interconnect structure with a skipvia in a step of manufacturing thereof according to one embodiment of present invention. More particularly, embodiments of present invention provide planarizing a top surface of the interconnect structure 10 by applying a CMP process to remove excessive portions of the first conductive material of Cu of the third metal line 321, and excessive portions of the conductive liner 332 and barrier layer 331 above the third ILD layer 300. The planarizing process thereby exposes a top surface of the third ILD layer 300 and a top surface of the third metal line 321 that is coplanar with the top surface of the third ILD layer 300.

Embodiments of present invention provide using Ru in forming the skipvia 311 thereby significantly reduced or eliminated the possibility of creating void in the skipvia 311. In the meantime, embodiments of present invention provide forming the third metal line 321 above the skipvia 311, by using Cu instead of Ru to reduce resistance of the third metal line. Moreover, embodiments of present invention enable forming the third metal line 321 directly on top of the skipvia 311 without the barrier layer 331 in-between, which further reduces the resistance between the third metal line 321 and the skipvia 311 or between the third metal line 321 and the contact via 312. By using Cu, instead of Ru, in forming the third metal line, embodiments of present invention further remove the difficulty in performing the challenging CMP process of Ru, should Ru be used in forming the third metal line 321. Additionally, with the skipvia 311 and contact via 312 of Ru material, effectively working as blocking boundary, high electromigration performance of the third metal line 321 is also expected.

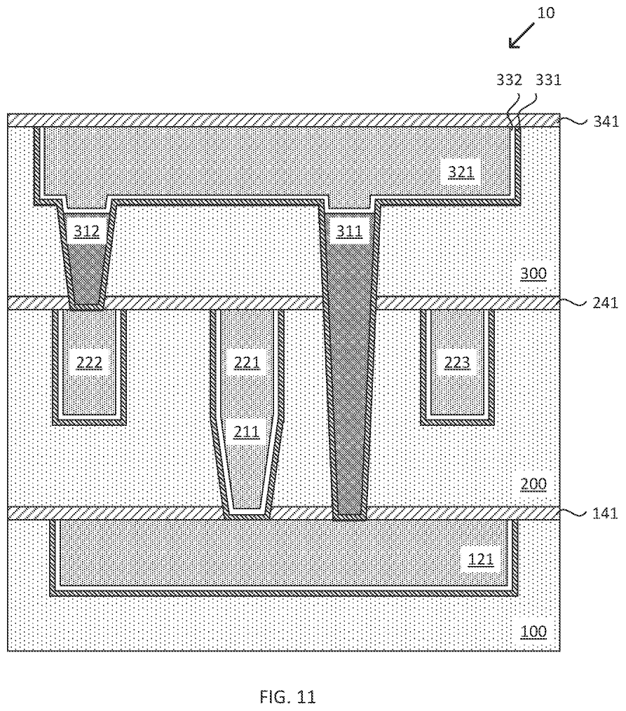

FIG. 11 is a demonstrative illustration of cross-sectional view of an interconnect structure with a skipvia in a step of manufacturing thereof according to one embodiment of present invention. More particularly, embodiments of present invention provide forming a dielectric cap layer 341 on top of the third metal line 321 and the third ILD layer 300. The dielectric cap layer 341 may be a layer of SiCN and may be formed through a CVD, PVD or ALD process.

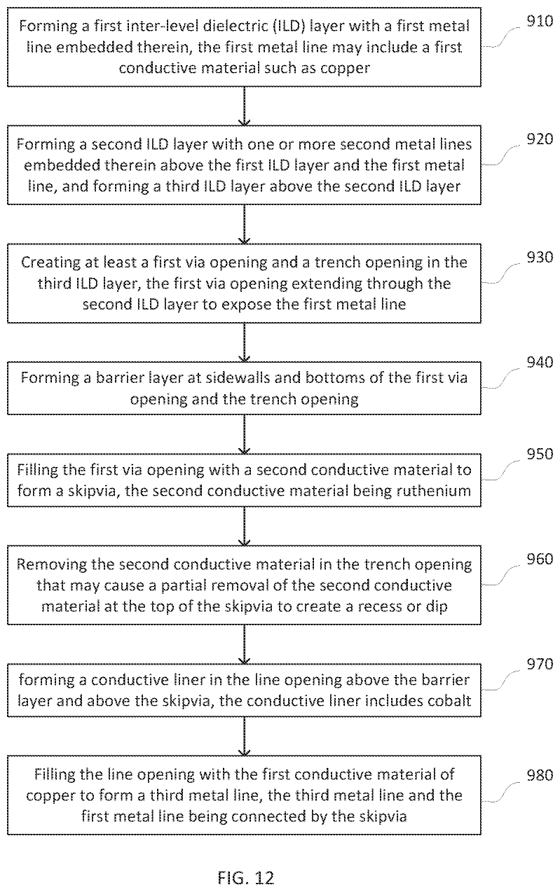

FIG. 12 is a demonstrative illustration of a flow-chart of a method of manufacturing an interconnect structure according to embodiments of present invention. The method includes (910) forming a first inter-level dielectric (ILD) layer with a first metal line embedded therein, and the first metal line may include or may be made of a first conductive material such as, for example, copper; (920) forming a second ILD layer, with one or more second metal lines embedded therein, above the first ILD layer and the first metal line, and forming a third ILD layer above the second ILD layer and the one or more second metal lines; (930) creating at least a first via opening and a trench opening through, for example, a damascene patterning process in the third ILD layer, wherein the first via opening may extend through the second ILD layer to expose the first metal line in the first ILD layer; (940) forming a barrier layer at sidewalls and bottoms of the first via opening and the trench opening; (950) filling the first via opening with a second conductive material to form a skipvia and the second conductive material may be, for example, ruthenium; (960) removing the second conductive material in the trench opening that may cause a partial removal of the second conductive material at the top of the skipvia to create a recess or dip; (970) forming a conductive liner of, for example, cobalt in the trench opening above the barrier layer and above the skipvia; and (980) filling the trench opening with the first conductive material to form a third metal line, wherein the third metal line and the first metal line are connected by the skipvia.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions above have been presented for the purposes of illustration of various embodiments of present invention and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. An interconnect structure comprising:
a first metal line in a first inter-level dielectric (ILD) layer;
one or more second metal lines in a second ILD layer above the first metal line and above the first ILD layer;
a third metal line in a third ILD layer above the one or more second metal lines and above the second ILD layer; and
a skipvia connecting the third metal line with the first metal line,
wherein the first, the one or more second, and the third metal lines are made of a first conductive material and the skipvia is made of a second conductive material, the first conductive material being different from the second conductive material.

2. The interconnect structure of claim 1, wherein the second conductive material is ruthenium (Ru).

3. The interconnect structure of claim 2, wherein the first conductive material is copper (Cu).

4. The interconnect structure of claim 1, further comprising a first contact via connecting one of the one or more second metal lines with the first metal line, wherein the first contact via is made of the first conductive material.

5. The interconnect structure of claim 4, further comprising a second contact via connecting the third metal line with another one of the one or more second metal lines, wherein the second contact via is made of the second conductive material.

6. The interconnect structure of claim 1, further comprising a barrier layer directly surrounding sidewalls and a bottom of the skipvia.

7. The interconnect structure of claim 6, further comprising a conductive liner directly lining the third metal line, and wherein the conductive liner is substantially surrounded by the barrier layer.

8. The interconnect structure of claim 7, wherein the conductive liner is on top of and in direct contact with the skipvia.

9. The interconnect structure of claim 7, wherein the barrier layer is a layer of tantalum-nitride (TaN) and the conductive liner is a layer of cobalt (Co).

10. An interconnect structure comprising:
a first metal line in a first inter-level dielectric (ILD) layer;
multiple second metal lines in a second ILD layer above the first metal line and above the first ILD layer;
a third metal line in a third ILD layer above the multiple second metal lines and above the second ILD layer; and
a skipvia between the third metal line and the first metal line,
wherein the first, the multiple second, and the third metal lines comprise a first conductive material and the skipvia comprises a second conductive material, the first conductive material being different from the second conductive material.

11. The interconnect structure of claim 10, wherein the first conductive material is copper (Cu) and the second conductive material is ruthenium (Ru).

12. The interconnect structure of claim 11, further comprising a first contact via between one of the multiple second metal lines with the first metal line, wherein the first contact via comprises the first conductive material.

13. The interconnect structure of claim 12, further comprising a second contact via between the third metal line with another one of the multiple second metal lines, wherein the second contact via comprises the second conductive material.

14. The interconnect structure of claim 10, further comprising a barrier layer directly surrounding the skipvia, the barrier layer being a layer of tantalum-nitride (TaN).

15. The interconnect structure of claim 14, wherein the third metal line is surrounded by a conductive liner, the conductive liner being a layer of cobalt (Co) and surrounded by the barrier layer.

16. The interconnect structure of claim 15, wherein the third metal line includes a lowered portion, the lowered portion having a step shape and a bottom thereof being covered by the conductive liner, the conductive liner being directly on top of the skipvia.

17. A method of forming an interconnect structure, the method comprising:
forming a first inter-level dielectric (ILD) layer with a first metal line of a first conductive material embedded therein;
forming a second ILD layer, with multiple second metal lines of the first conductive material embedded therein, on top of the first ILD layer;
forming a third ILD layer on top of the second ILD layer;
creating a first via opening in the third ILD layer, the first via opening extending through the second ILD layer to expose the first metal line in the first ILD layer;
filling the first via opening with a second conductive material to form a skipvia; and
forming a third metal line of the first conductive material in the third ILD layer, the third metal line being on top of and in contact with the skipvia,
wherein the first conductive material is copper (Cu), and the second conductive material is ruthenium (Ru).

18. The method of claim 17, further comprising:
creating a trench opening in a damascene patterning and etching process in the third ILD layer;
before filling the first via opening, forming a barrier layer at sidewalls and bottoms of the first via opening and the trench opening; and
after filling the first via opening, removing the second conductive material in the trench opening and recessing the second conductive material in the first via opening.

19. The method of claim 18, further comprising:
before forming the third metal line, forming a conductive liner in the trench opening above the barrier layer and directly above the skipvia; and
filling the trench opening with the first conductive material to form the third metal line.

20. The method of claim 17, further comprising:
creating a second via opening in the third ILD layer to expose one of the multiple second metal lines in the second ILD layer; and
filling the second via opening with the second conductive material to form a contact via.
